(19) United States
(12) Patent Application Publication
(10) Pub. No.: US 2015/0255702 A1
(43) Pub. Date: Sep. 10, 2015

(54) ELECTRONIC DEVICE, ELECTRONIC APPARATUS AND MOVING OBJECT

(71) Applicant: Seiko Epson Corporation, Tokyo (JP)

(72) Inventors: Yuichi TAKEBAYASHI, Minowa (JP); Yoshiaki MATSUMOTO, Ina (JP)

(21) Appl. No.: 14/640,127

(22) Filed: Mar. 6, 2015

(30) Foreign Application Priority Data
Mar. 10, 2014 (JP) 2014-046981

(51) Int. Cl. H01L 41/053; H05K 5/03; H05K 1/02; H03H 9/17; H03H 9/25

(52) U.S. Cl. CPC H01L 41/053; H03H 9/17; H03H 9/25; H05K 1/0298; H05K 5/03

(57) ABSTRACT

An electronic device includes a base substrate in which first and second substrates are laminated and a lid which is bonded to the base substrate. The base substrate includes notched portions which are provided on lateral sides and castellations which are disposed in the notched portions. The lid includes a main body which is disposed so as to face the base substrate, and claw portions, protruding from the main body, which are disposed within the notched portions. A length of the claw portions is equal to or less than a thickness of the first substrate.

### BACKGROUND

1. Technical Field

The present invention relates to an electronic device, an electronic apparatus and a moving object.

2. Related Art

Hitherto, oscillators using a SAW (Surface Acoustic Wave) resonator or a quartz crystal resonator have been known, and widely used as a reference frequency source, an oscillation source, or the like of various electronic apparatuses.

An electronic device disclosed in JP-A-2012-64639 includes a circuit substrate having electronic parts mounted thereon, and a metal case which is bonded to the circuit substrate. In addition, a notched portion extending from the upper surface to the lower surface is provided on the lateral side of the circuit substrate, and an electrode is provided in the notched portion. On the other hand, the metal case has a claw portion extending downward, and is configured such that this claw portion is inserted into the notched portion of the circuit substrate, and is bonded to the electrode provided in the notched portion through solder. In such an electronic device disclosed in JP-A-2012-64639, the circuit substrate is formed in a single-layered structure, and a laminated substrate having a large number of substrates laminated therein is not considered. When the circuit substrate is formed of a laminated substrate, at least one green sheet may be misaligned with respect to the other green sheets, for example, during the lamination of the green sheets, and thus the shape of the notched portion may collapse. In such a case, the claw portion of a metal cover catches on the notched portion, and thus the claw portion is not able to be inserted into the notched portion up to a predetermined depth, which leads to a problem in that the metal cover is not able to be disposed at a correct position.

### SUMMARY

An advantage of some aspects of the invention is to provide an electronic device, an electronic apparatus and a moving object which are capable of disposing a lid at a desired position with respect to a base substrate.

The invention can be implemented as the following application examples.

### APPLICATION EXAMPLE 1

This application example is directed to an electronic device including a base substrate including a first substrate and a second substrate which are laminated, and a lid which is bonded to the first substrate side of the base substrate. The base substrate is configured such that a notched portion is provided on a lateral side throughout the second substrate from the first substrate in the lamination direction, and that a metal film is present on an inner surface of a region of the first substrate in the notched portion. The lid includes a main body that faces the base substrate, and a first claw portion, protruding from the main body to a region facing the notched portion, which is bonded to the metal film through a bonding member. A length of the first claw portion along the lamination direction is equal to or less than a thickness of the first substrate along the lamination direction.

With this configuration, even when the lamination misalignment between the first substrate and the second substrate is caused, the possibility of the claw portion of the lid not being able to be inserted into the notched portion up to a predetermined depth can be reduced, and thus it is possible to dispose the lid at a desired position with respect to the base substrate.

### APPLICATION EXAMPLE 2

It is preferable that the electronic device according to this application example further includes a second claw portion, extending from the first claw portion, of which a length in a direction intersecting a direction in which the first claw portion protrudes from the main body is shorter than that of the first claw portion.

With this configuration, even when the lamination misalignment between the first substrate and the second substrate is caused, the possibility of the claw portion of the lid not being able to be inserted into the notched portion up to a predetermined depth can be reduced, and thus it is possible to dispose the lid at a desired position with respect to the base substrate. In addition, since the first claw portion and the second claw portion are included, the connection between the entire claw portion and the metal film can be made stronger, and thus it is possible to connect the lid to the base substrate more strongly.

### APPLICATION EXAMPLES 3 AND 4

In the electronic devices according to these application examples, it is preferable that the lid and the bonding member have a conductive property, the lid is electrically connected to the metal film through the bonding member, and that the metal film is connected to a reference potential.

With this configuration, it is possible to dispose the lid at a desired position with respect to the base substrate, and to make the lid function as a shield layer.

### APPLICATION EXAMPLES 5, 6, AND 7

In the electronic devices according to these application examples, it is preferable that the first substrate is larger in thickness than the second substrate.

With this configuration, since it is possible to dispose the lid at a desired position with respect to the base substrate, and to make the claw portion as long as possible, the lid can be more reliably connected to the base substrate.

### APPLICATION EXAMPLES 8, 9, AND 10

In the electronic devices according to these application examples, it is preferable that the base substrate has a cavity which is open to a main surface of the lid side, and that the main body of the lid has a cavity which is open to a main surface of the base substrate side.

With this configuration, it is possible to form a relatively wide space in the inside of a package which is constituted by the base substrate and the lid.

### APPLICATION EXAMPLES 11, 12, AND 13

It is preferable that the electronic devices according to these application examples further include an internal substrate, connected to the base substrate, within a space which is formed by a cavity of the base substrate and a cavity of the lid.

With this configuration, it is possible to use the internal substrate as a reinforcement member that reinforces the mechanical strength of the base substrate, and to improve the mechanical strength of the electronic device.

### APPLICATION EXAMPLES 14, 15, AND 16

In the electronic device according to these application examples, it is preferable that the internal substrate is provided with a resonator and a circuit which is connected to the resonator.

With this configuration, it is possible to effectively utilize the inside of a package which is constituted by the base substrate and the lid.

### APPLICATION EXAMPLE 17

This application example is directed to an electronic apparatus including the electronic device according to the application example described above.

With this configuration, it is possible to obtain an electronic apparatus having high reliability.

### APPLICATION EXAMPLE 18

This application example is directed to a moving object including the electronic device according to the application example described above.

With this configuration, it is possible to obtain an electronic apparatus having high reliability.

### BRIEF DESCRIPTION OF THE DRAWINGS

The invention will be described with reference to the accompanying drawings, wherein like numbers reference like elements.

FIG. 1 is a perspective view illustrating an electronic device according to a first embodiment of the invention.

FIG. 2 is a cross-sectional view illustrating the electronic device shown in FIG. 1.

FIGS. 3A and 3B are plan views illustrating a base substrate included in the electronic device shown in FIG. 1;

FIG. 3A is a top view, and FIG. 3B is a see-through view when seen from the upper side.

FIG. 4 is a cross-sectional view illustrating the electronic device shown in FIG. 1.

FIGS. 5A and 5B are diagrams illustrating a claw portion included in the electronic device shown in FIG. 1; FIG. 5A is a side view, and FIG. 5B is a top view.

FIGS. 6A and 6B are side views illustrating an effect of the claw portion shown in FIGS. 5A and 5B.

FIG. 7 is a perspective view illustrating a state where a lid of the electronic device shown in FIG. 1 is removed.

FIG. 8 is a plan view illustrating a support substrate included in the electronic device shown in FIG. 1.

FIG. 9 is a block diagram illustrating a circuit included in the electronic device shown in FIG. 1.

FIGS. 10A and 10B are a cross-sectional view and a plan view, respectively, illustrating a SAW resonator included in the electronic device shown in FIG. 1.

FIG. 11 is a side view illustrating an electronic device according to a second embodiment of the invention.

FIG. 12 is a side view illustrating an electronic device according to a third embodiment of the invention.

FIG. 13 is a side view illustrating the electronic device according to the third embodiment of the invention.

FIG. 14 is a perspective view illustrating a configuration of a mobile-type (or note-type) personal computer to which an electronic apparatus according to the invention is applied.

FIG. 15 is a perspective view illustrating a configuration of a cellular phone (also including PHS) to which an electronic apparatus according to the invention is applied.

FIG. 16 is a perspective view illustrating a configuration of a digital still camera to which an electronic apparatus according to the invention is applied.

FIG. 17 is a perspective view illustrating an automobile to which a moving object according to the invention is applied.

### DESCRIPTION OF EXEMPLARY EMBODIMENTS

Hereinafter, an electronic apparatus, an electronic device and a moving object according to the invention will be described in detail on the basis of embodiments shown in the accompanying drawings.

### 1. Electronic Device

### First Embodiment

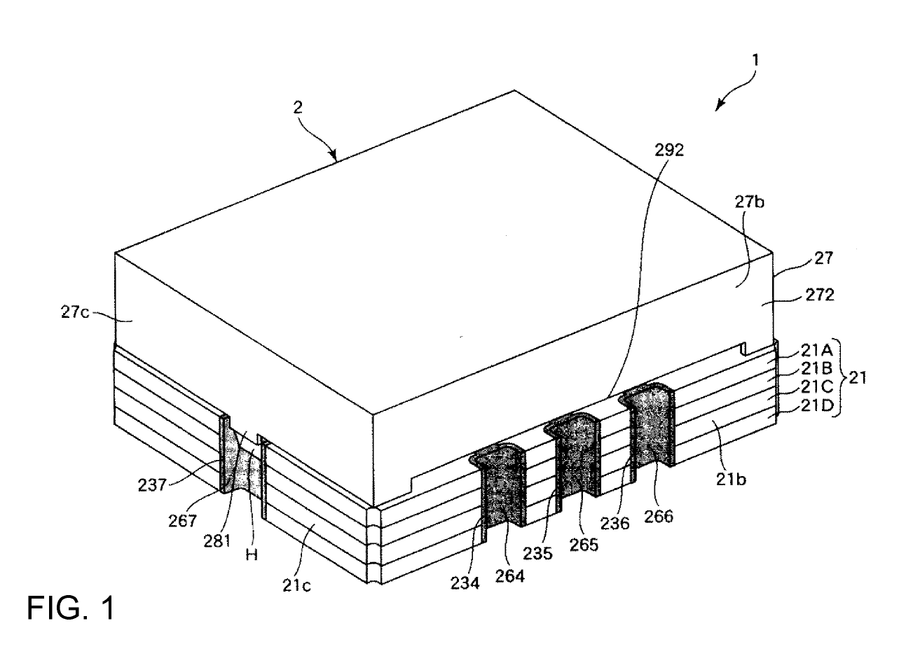

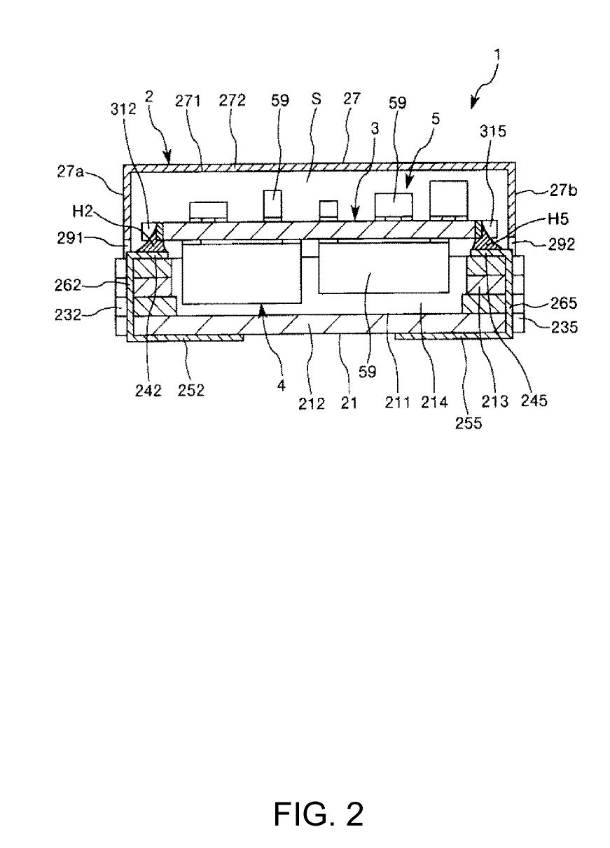

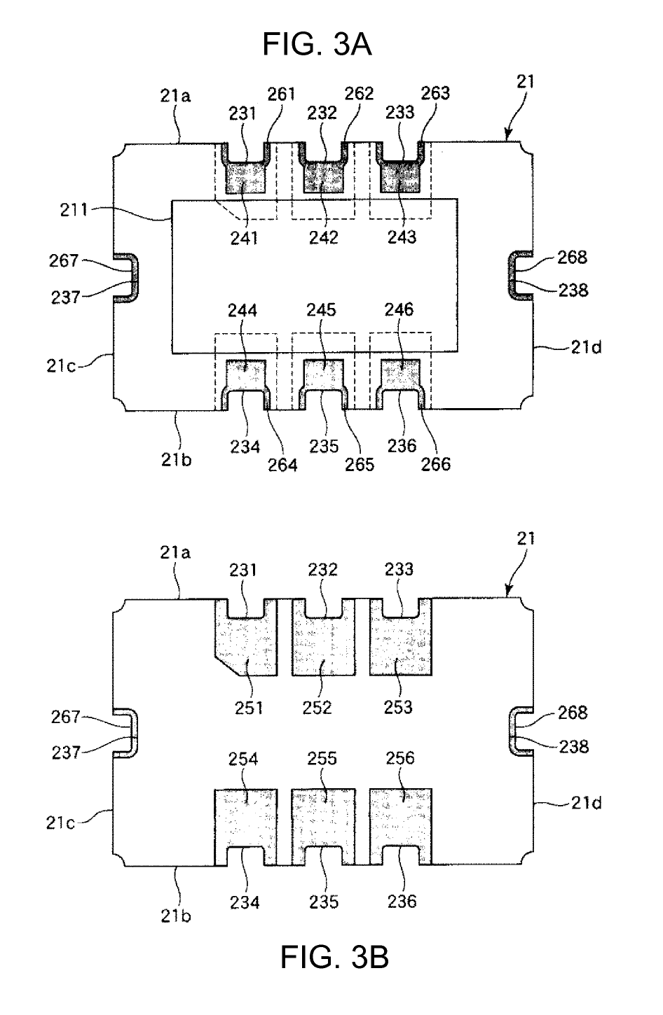

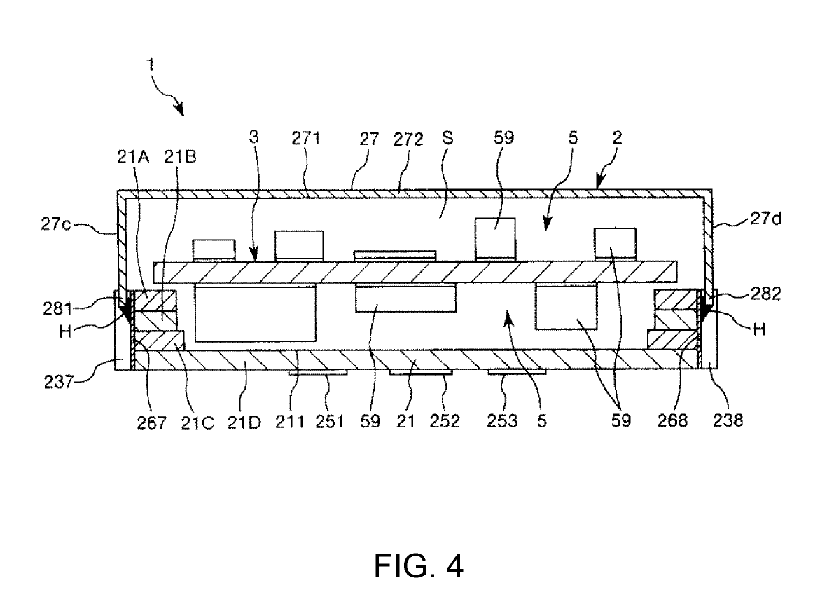

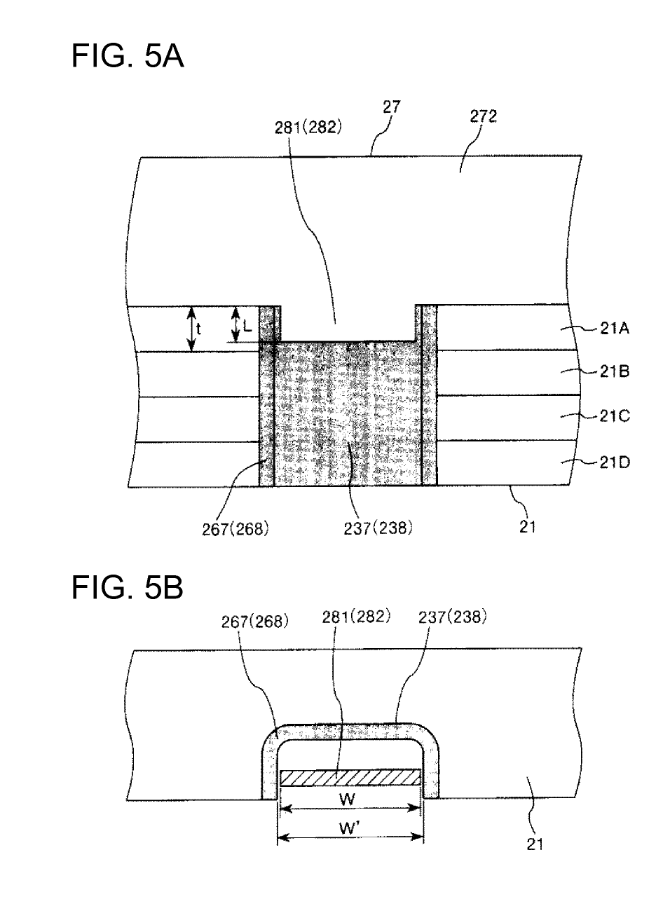

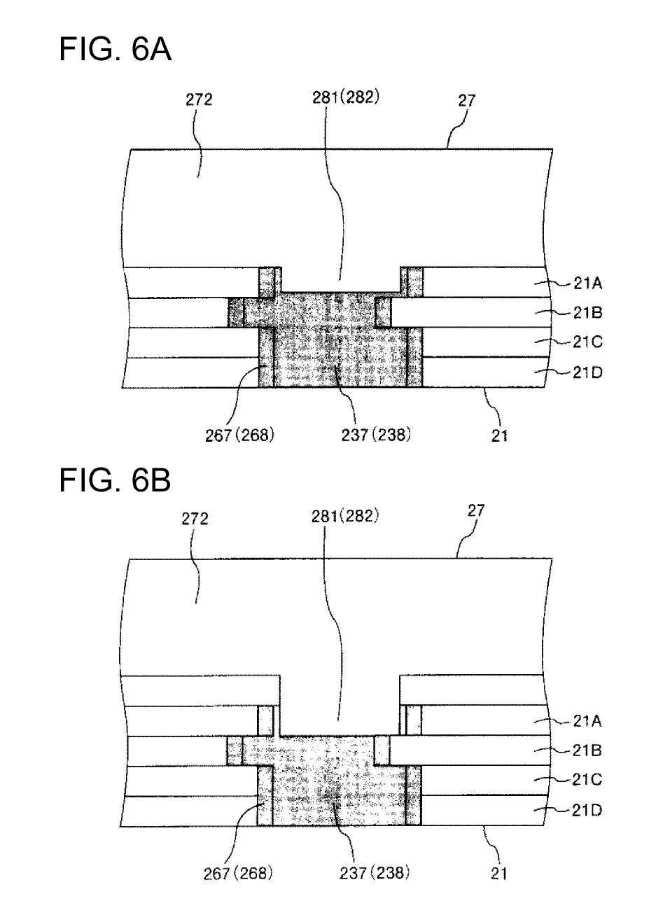

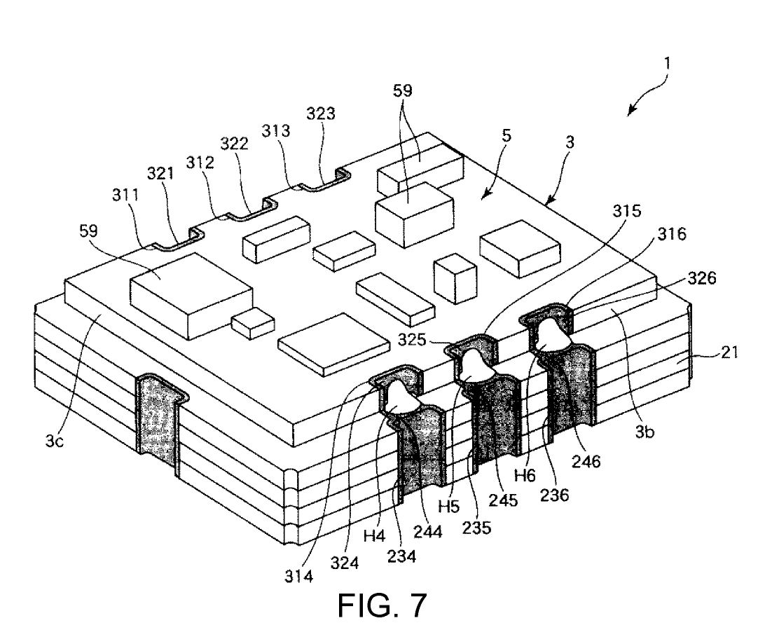

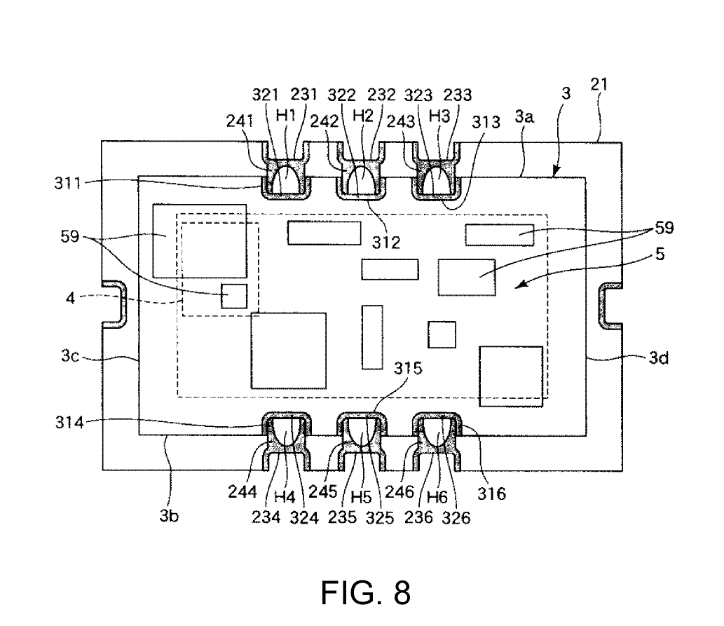

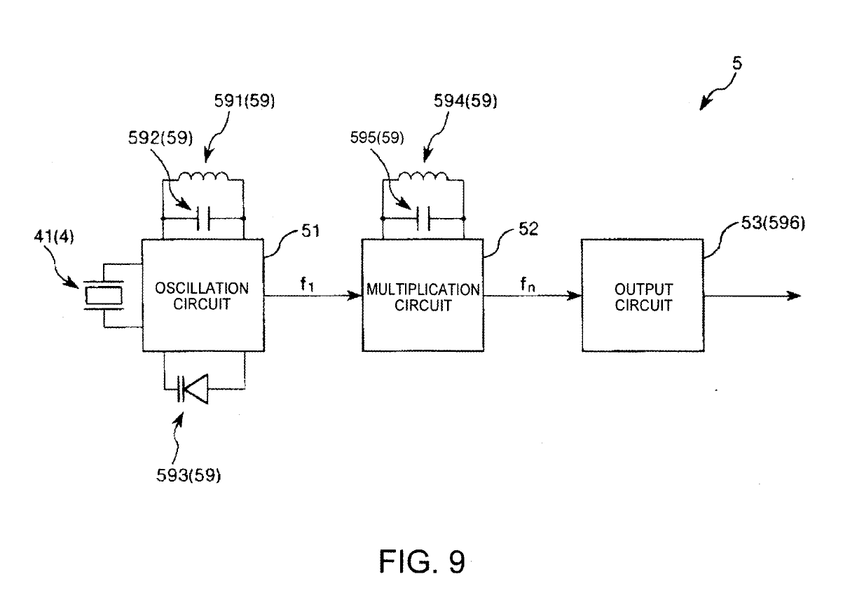

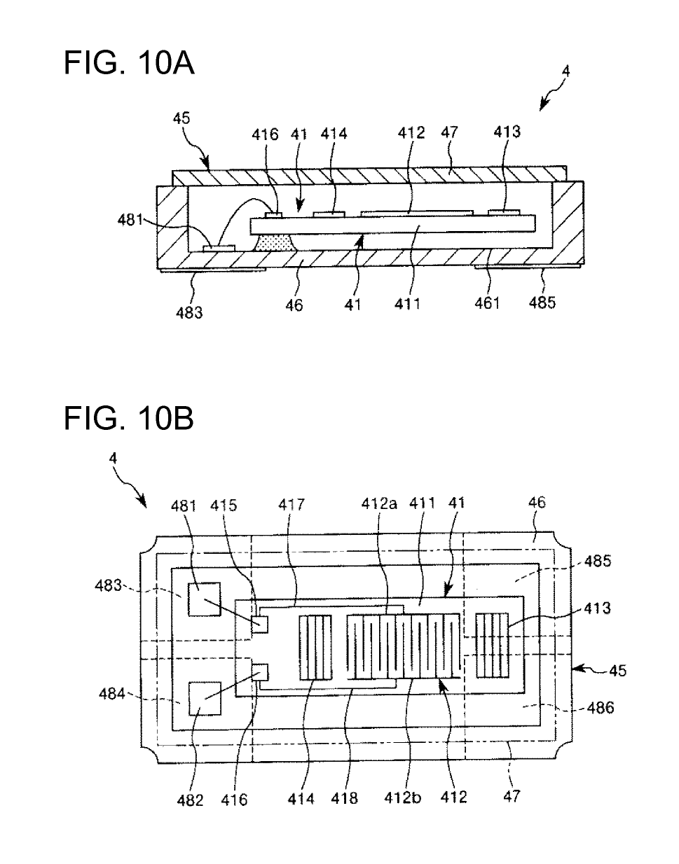

FIG. 1 is a perspective view illustrating an electronic device according to a first embodiment of the invention. FIG. 2 is a cross-sectional view illustrating the electronic device shown in FIG. 1. FIGS. 3A and 3B are plan views illustrating abase substrate included in the electronic device shown in FIG. 1; FIG. 3A is a top view, and FIG. 3B is a see-through view when seen from the upper side. FIG. 4 is a cross-sectional view illustrating the electronic device shown in FIG. 1. FIGS. 5A and 5B are diagrams illustrating a claw portion included in the electronic device shown in FIG. 1; FIG. 5A is a side view, and FIG. 5B is a top view. FIGS. 6A and 6B are side views illustrating an effect of the claw portion shown in FIGS. 5A and 5B. FIG. 7 is a perspective view illustrating a state where a lid of the electronic device shown in FIG. 1 is removed. FIG. 8 is a plan view illustrating a support substrate included in the electronic device shown in FIG. 1. FIG. 9 is a block diagram illustrating a circuit included in the electronic device shown in FIG. 1. FIGS. 10A and 10B are a cross-sectional view and a plan view, respectively, illustrating a SAW resonator included in the electronic device shown in FIG. 1. Meanwhile hereinafter, for convenience of description, an upper side in FIG. 2 is defined as “upper”, and a lower side is defined as “lower”.

An electronic device 1 shown in FIG. 1 includes a package 2, a support substrate (internal substrate) 3 which is fixed into the package 2, and a SAW resonator (resonator) 4 and a circuit 5 which are mounted onto the support substrate 3, and is an electronic device constituting a voltage controlled SAW oscillator (VCSO). Hereinafter, each of these components will be sequentially described.

### Package

As shown in FIGS. 1 and 2, the package 2 includes a base substrate 21 and a lid 27 which is bonded to the base substrate 21. An internal space S is provided between the base substrate 21 and the lid 27 within the package 2, the support substrate 3, the SAW resonator 4 and the circuit 5 being stored and disposed in this internal space S.

As shown in FIGS. 3A and 3B, the base substrate 21 is formed in a box shape having a cavity 211 which is open to the upper surface. In other words, the base substrate 21 includes a plate-like bottom plate 212, a frame-like sidewall 213 which is disposed upright from the marginal portion of the upper surface of the bottom plate 212, and a region 214 which is surrounded by the sidewall 213. In addition, the base substrate 21 is a laminated substrate in which a first substrate 21A, a second substrate 21B, a third substrate 21C and a fourth substrate 21D are laminated in this order from the upper surface side, and is configured such that the bottom plate 212 is formed of the fourth substrate 21D and that the sidewall 213 is formed of the first, second, and third substrates 21A, 21B, and 21C. Meanwhile, in the present embodiment, the base substrate 21 is a four-layered laminated body, but when the base substrate is a laminated body formed of two or more layers, the number of layers is not particularly limited.

Such a base substrate 21 is formed in an approximately rectangular shape when seen in plan view, and includes a pair of lateral sides 21a and 21b extending in a long-axis direction and a pair of lateral sides 21c and 21d extending in a short-axis direction. In addition, three notched portions 231, 232, and 233 (passing through the base substrate 21 in a thickness direction) extending from the upper surface to the lower surface are provided side by side on the lateral side 21a, and these notched portions 231, 232, and 233 are disposed near the central portion so as to keep away from both ends of the lateral side 21a. Similarly to this, three notched portions 234, 235, and 236 extending from the upper surface to the lower surface are also provided side by side on the lateral side 21b, and these notched portions 234, 235, and 236 are disposed near the central portion so as to keep away from both ends of the lateral side 21b.

In addition, a notched portion 237 extending from the upper surface to the lower surface is provided on the lateral side 21c, and this notched portion 237 is provided at the central portion of the lateral side 21c. Similarly to this, a notched portion 238 extending from the upper surface to the lower surface is also provided on the lateral side 21d, and this notched portion 238 is provided at the central portion of the lateral side 21d. Meanwhile, when the notched portion 237 and the notched portion 238 are respectively disposed so as to keep away from the both ends of the lateral side 21c and both ends of the lateral side 21d, the positions thereof are not particularly limited.

In addition, six internal terminals 241, 242, 243, 244, 245, and 246 are provided on the upper surface of the base substrate 21, and six external connection terminals (user terminals) 251, 252, 253, 254, 255, and 256 are provided on the lower surface of the base substrate 21. For example, a power supply terminal, a GND terminal, an output terminal, and the like are included in these external connection terminals 251 to 256. In addition, castellations (metal films) 261, 262, 263, 264, 265, 266, 267, and 268 are disposed in the notched portions 231, 232, 233, 234, 235, 236, 237, and 238, respectively.

The internal terminal 241 and the external connection terminal 251 are disposed side by side in the notched portion 231, and are electrically connected to each other through the castellation 261. Similarly, the internal terminal 242 and the external connection terminal 252 are disposed side by side in the notched portion 232, and are electrically connected to each other through the castellation 262. In addition, the internal terminal 243 and the external connection terminal 253 are disposed side by side in the notched portion 233, and are electrically connected to each other through the castellation 263. In addition, the internal terminal 244 and the external connection terminal 254 are disposed side by side in the notched portion 234, and are electrically connected to each other through the castellation 264. In addition, the internal terminal 245 and the external connection terminal 255 are disposed side by side in the notched portion 235, and are electrically connected to each other through the castellation 265. In addition, the internal terminal 246 and the external connection terminal 256 are disposed side by side in the notched portion 236, and are electrically connected to each other through the castellation 266. In addition, each of the castellations 267 and 268 are electrically connected to the GND terminal included in the external connection terminals 251 to 256 through a wiring which is formed inside the base substrate 21.

Such a base substrate 21 is obtained by laminating a plurality of substrates which are formed of a ceramic green sheet such as, for example, an aluminum oxide substance, an aluminum nitride substance, a silicon carbide substance, a mullite substance, or a glass ceramic substance, and sintering this laminated body. In addition, each of the internal terminals 241 to 246, the external connection terminals 251 to 256, and the castellations 261 to 268 is obtained by coating, for example, a plated layer of gold (Au), copper (Cu) or the like on an underlying layer of tungsten (W), molybdenum (Mo) or the like.

On the other hand, as shown in FIGS. 1 and 4, the lid 27 includes a box-shaped main body 272 having a cavity 271 which is open to the lower surface, and claw portions (first claw portions) 281 and 282 protruding downward from the main body 272. The main body 272 has an approximately rectangular outer shape corresponding to the base substrate 21 when seen in plan view, and has a pair of lateral sides 27a and 27b extending in a long-axis direction and a pair of lateral sides 27c and 27d extending in a short-axis direction. In addition, concave omission portions 291 and 292 which are open to the lower surface are formed on the lateral sides 27a and 27b, and the contact between the lid 27 and the internal terminals 241 to 246 is prevented by the omission portions 291 and 292.

In addition, the claw portions 281 and 282 protrude downward from the lateral sides 27c and 27d, and are inserted (disposed) into the notched portions 237 and 238 of the base substrate 21. The claw portions 281 and 282 and the castellations 267 and 268, located along the notched portions 237 and 238, which are disposed on the lateral sides of the base substrate are bonded to each other through solder (bonding member) H, and thus the lid 27 is bonded to the base substrate 21. Meanwhile, as the bonding member, various metal brazing materials such as gold solder or silver solder, or a conductive bonding member such as a conductive adhesive may be used in addition to the solder H, and the claw portions 281 and 282 and the castellations 267 and 268 may be melted and bonded to each other by welding or the like.

Here, as shown in FIGS. 5A and 5B, it preferable that the width W of the claw portions 281 and 282 is almost equal to the width W′ of the notched portions 237 and 238 (castellations 267 and 268) on a surface where the claw portions 281 and 282 are located. More specifically, it is preferable that the width W satisfies the relation of, for example, 0.9W′≦W≦1.1W′. Thereby, the misalignment of the lid 27 in an in-plane direction (short-axis direction and long-axis direction) with respect to the base substrate 21 is reduced, and thus the lid 27 can be more accurately positioned with respect to the base substrate 21. Meanwhile, when the relation of W′<W is also satisfied in the above range, the claw portions 281 and 282 are particularly fitted to the notched portions 237 and 238, and thus the base substrate 21 and the lid 27 can be bonded to each other more strongly.

In addition, as shown in FIGS. 5A and 5B, the length L of the claw portions 281 and 282 is equal to or less than the thickness t of the first substrate 21A. That is, the relation of is satisfied. Thereby, the lid 27 can be disposed at a desired position more reliably with respect to the base substrate 21. Specifically, as described above, since the base substrate 21 is formed of a laminated substrate in which the first to fourth substrates 21A to 21D are laminated, lamination misalignment may occur during manufacturing, and, for example, the second substrate 21B may be misaligned with respect to the other substrates 21A, 21C, and 21D. Even in such a case, when the relation of L≦t is satisfied, as shown in FIG. 6A, the claw portions 281 and 282 of the lid 27 can be inserted into the notched portions 237 and 238 up to a predetermined depth (until the lower surface of the main body 272 comes into contact with the upper surface of the base substrate 21). In this manner, when the relation of L≦t is satisfied, the lid 27 can be disposed at a desired position with respect to the base substrate 21. On the other hand, when the relation of L>t is satisfied, as shown in FIG. 6B, the apex of the claw portions 281 and 282 strikes on the second substrate 21B. Thereby, the claw portions are not able to be inserted any more, and thus the claw portions 281 and 282 are not able to be inserted into the notched portions 237 and 238 up to a predetermined depth. For this reason, the lid 27 is not able to be disposed at a desired position with respect to the base substrate 21.

Such a lid 27 is formed of a metal material (material having a conductive property). Thereby, since the lid 27 is electrically connected to the GND terminal (reference voltage) through the solder H and the castellations 267 and 268, the lid 27 functions as a shield layer that cuts off or attenuates a signal (noise) from the outside. Therefore, the electronic device 1 having excellent oscillation characteristics and high reliability is obtained. Meanwhile, as a metal material constituting the lid 27, a material having a linear expansion coefficient approximate to that of the base substrate 21 may be preferably used. For example, when ceramics are used as the configuration material of the base substrate 21, it is preferable to use an alloy such as Kovar. In addition, the lid 27 may be formed of an insulating member which is formed of, for example, a member such as ceramic, resin or glass, or a member having these materials mixed in, and may have a configuration in which a metal is attached onto the surface of the lid by a method such as plating, evaporation, sputtering, application or printing, or a method incorporating these processes.

### Support Substrate

The support substrate 3 is formed of a low-temperature co-fired ceramic substrate (LTCC substrate). Thereby, the support substrate 3 having a high strength is obtained. In addition, it is possible to simultaneously form a wiring pattern, and to reduce the number of processes for manufacturing the electronic device 1. Meanwhile, the support substrate 3 may be a single-layered substrate, and may be a multi-layered substrate. In addition, the support substrate 3 is not limited to the low-temperature co-fired ceramic substrate. Besides, for example, a ceramic substrate other than the low-temperature co-fired ceramic substrate, a resin substrate (printed substrate) formed of glass epoxy or other configuration members, a glass substrate, or the like may be used therein.

Such a support substrate 3 is formed in a plate shape. In addition, as shown in FIGS. 7 and 8, the support substrate 3 is formed in a rectangular shape corresponding to the base substrate 21 when seen in plan view, and the lateral side thereof for connecting an upper surface (first main surface) and a lower surface (second main surface) has a pair of lateral sides (first and second lateral sides) 3a and 3b extending in a long-axis direction and a pair of lateral sides (third and fourth lateral sides) 3c and 3d extending in a short-axis direction.

In addition, three notched portions 311, 312, and 313 extending from the upper surface to the lower surface are provided side by side on the lateral side 3a, and these notched portions 311, 312, and 313 are disposed near the central portion so as to keep away from both ends of the lateral side 3a. Similarly to this, three notched portions 314, 315, and 316 extending from the upper surface to the lower surface are also provided side by side on the lateral side 3b, and these notched portions 314, 315, and 316 are disposed near the central portion so as to keep away from both ends of the lateral side 3b. Castellations 321, 322, 323, 324, 325, and 326 are formed in these notched portions 311, 312, 313, 314, 315, and 316, respectively.

In addition, as shown in FIG. 8, when seen in plan view, the notched portions 311 to 316 are located further inside (at the center side of the base substrate 21) than the notched portions 231 to 236 which are formed in the base substrate 21. Further, the notched portion 311 is provided so as to be lined up with the notched portion 231 and overlap the internal terminal 241. Similarly to this, the notched portion 312 is provided so as to be lined up with the notched portion 232 and overlap the internal terminal 242, the notched portion 313 is provided so as to be lined up with the notched portion 233 and overlap the internal terminal 243, the notched portion 314 is provided so as to be lined up with the notched portion 234 and overlap the internal terminal 244, the notched portion 315 is provided so as to be lined up with the notched portion 235 and overlap the internal terminal 245, and the notched portion 316 is provided so as to be lined up with the notched portion 236 and overlap the internal terminal 246.

The support substrate 3 having such a configuration is located so as to overlap the cavity 211 (region 214) when seen in plan view, and is fixed to the upper surface (main surface of the sidewall 213) of the base substrate 21 by six solders (fixing members) H1 to H6. A fixing member that fixes the support substrate 3 to the base substrate 21 is not limited to the solder. A metal brazing material such as, for example, gold solder or silver solder, or a conductive adhesive may be used therein, and the castellations 321, 322, 323, 324, 325, and 326 and the internal terminals 241, 242, 243, 244, 245, and 246 may be melted by welding or the like and be bonded to each other.

The solder H1 is located on the internal terminal 241, and has a fillet formed in the notched portion 311. Thereby, the support substrate 3 is fixed to the base substrate 21, and the internal terminal 241 and the castellation 321 are electrically connected to each other. Similarly, the solder H2 is located on the internal terminal 242, and has a fillet formed in the notched portion 312. Thereby, the support substrate 3 is fixed to the base substrate 21, and the internal terminal 242 and the castellation 322 are electrically connected to each other. In addition, the solder H3 is located on the internal terminal 243, and has a fillet formed in the notched portion 313. Thereby, the support substrate 3 is fixed to the base substrate 21, and the internal terminal 243 and the castellation 323 are electrically connected to each other. In addition, the solder H4 is located on the internal terminal 244, and has a fillet formed in the notched portion 314. Thereby, the support substrate 3 is fixed to the base substrate 21, and the internal terminal 244 and the castellation 324 are electrically connected to each other. In addition, the solder H5 is located on the internal terminal 245, and has a fillet formed in the notched portion 315. Thereby, the support substrate 3 is fixed to the base substrate 21, and the internal terminal 245 and the castellation 325 are electrically connected to each other. In addition, the solder H6 is located on the internal terminal 246, and has a fillet formed in the notched portion 316. Thereby, the support substrate 3 is fixed to the base substrate 21, and the internal terminal 246 and the castellation 326 are electrically connected to each other.

### Circuit

As shown in FIGS. 2, 7, and 8, the circuit 5 includes a wiring pattern (not shown) which is formed on the upper surface, the lower surface and the inside of the support substrate 3, and a plurality of circuit elements 59, mounted in the support substrate 3, which are connected to each other by the wiring pattern. The wiring pattern is connected to the castellations 321 to 326. Thereby, the wiring pattern and the external connection terminals 251 to 256 are electrically connected to each other.

As shown in FIG. 9, such a circuit 5 includes an oscillation circuit 51 that oscillates the SAW resonator 4, a multiplication circuit 52 that increases an output frequency f1 from the oscillation circuit 51 n times, and an output circuit 53 that converts an output frequency fn (=f1×n) from the multiplication circuit 52 into a predetermined output format (such as CMOS, LV-PECL, or LVDS) to output the resultant. The multiplication circuit 52 includes a bandpass filter, and outputs the output frequency fn by passing the frequency fn which is superimposed on the output frequency f1 from the oscillation circuit 51 and attenuating the other frequencies ( . . . f1×(n−1), f1×(n×1) . . . ).

Each of the oscillation circuit 51 and the multiplication circuit 52 of the present embodiment is a circuit having a plurality of discrete parts lined up therein, and the output circuit 53 is an integrated circuit. Therefore, the circuit element 59 includes, for example, a chip coil (chip inductor) 591, a chip capacitor 592, a varicap (variable capacitance diode) 593 and a resistor which are included in the oscillation circuit 51, a chip coil (chip inductor) 594, a chip capacitor 595 and a resistor, included in the multiplication circuit 52, that constitute a bandpass filter, an IC chip 596 constituting the output circuit 53, and the like. The oscillation circuit 51 and the multiplication circuit 52 may also be configured as an integrated circuit similarly to the output circuit 53, and at least two circuits of the oscillation circuit 51, the multiplication circuit 52, and the output circuit 53 may be formed within one integrated circuit.

When the oscillation circuit 51 and the multiplication circuit 52 are not configured as an integrated circuit, but configured as a circuit having discrete parts lined up therein, for example, it is thus possible to exhibit the following effects. It is possible to adjust the output frequency from the oscillation circuit 51 by exchanging the chip coil 591 or the chip capacitor 592, included in the oscillation circuit 51, for an element having different inductance or capacitance, and to thereby make the output frequency f1 conform to a desired frequency. In addition, it is possible to adjust the bandpass of the bandpass filter by exchanging the chip coil 594 or the chip capacitor 595, included in the multiplication circuit 52, for an element having different inductance or capacitance, and to thereby suppress a spurious signal (unnecessary signal) by attenuating frequencies other than the output frequency fn. In this manner, the oscillation circuit 51 and the multiplication circuit 52 are not configured as an integrated circuit, but configured as a circuit having discrete parts lined up therein, and thus it is possible to easily perform various types of adjustment of the electronic device 1. Meanwhile, since the output circuit 53 has little scope to implement an adjustment function unlike the oscillation circuit 51 or the multiplication circuit 52, the output circuit being configured as an integrated circuit makes it possible to achieve a reduction in the size of the circuit 5.

Meanwhile, the circuit 5 may include, for example, a temperature compensation circuit, in addition to these circuits 51, 52, and 53. In addition, when a frequency to be output from the electronic device 1 can be output from the oscillation circuit 51, the multiplication circuit 52 may be omitted. In addition, the circuit 5 includes the SAW resonator 4 for outputting a first frequency signal, the oscillation circuit 51 and the multiplication circuit 52 (first group), the SAW resonator 4, the oscillation circuit 51 and the multiplication circuit 52 (second group) for outputting a second frequency signal having a frequency different from that of the first frequency signal, a switching circuit that switches between the first group and the second group, and the output circuit 53, and may be configured to be capable of selecting and outputting one of the first frequency signal and the second frequency signal from the output circuit 53 by switching between the first group and the second group using the switching circuit.

### SAW Resonator

As shown in FIGS. 10A and 10B, the SAW resonator 4 includes a package 45 and a SAW resonator element 41 which is housed in the package 45.

The package 45 includes a ceramic base substrate 46 having a cavity 461 which is open to the upper surface, and a plate-like metal cover 47 which is bonded to the ceramic base substrate 46 so as to block an opening of the cavity 461. In addition, the bottom of the cavity 461 is provided with internal terminals 481 and 482 which are electrically connected to the SAW resonator element 41, and the lower surface of the ceramic base substrate 46 is provided with external connection terminals 483 and 484 which are electrically connected to the internal terminals 481 and 482 through a via (through-electrode) which is not shown, and dummy terminals 485 and 486 for bonding with the support substrate 3.

The SAW resonator element 41 includes a quartz crystal substrate 411 having a longitudinal shape, an IDT (Inter Digital Transducer) 412 which is provided on the upper surface of the quartz crystal substrate 411, a pair of reflectors 413 and 414 which are disposed on both sides of the IDT 412, bonding pads 415 and 416, and extraction electrodes 417 and 418 which are electrically connected to the IDT 412 and the bonding pads 415 and 416. Meanwhile, a quartz crystal resonator element using quartz crystal as a substrate material, for example, an AT cut or SC cut quartz crystal resonator element, a MEMS (Micro Electro Mechanical Systems) resonator element, or a resonator element using other substrate materials may be used instead of the SAW resonator element 41. In addition, as the substrate material of the SAW resonator element 41, the MEMS resonator element, or the resonator element, a piezoelectric material such as piezoelectric single crystal such as lithium tantalate or lithium niobate, or piezoelectric ceramics such as lead zirconate titanate, a silicon semiconductor material, or the like may be used in addition to quartz crystal. As excitation means of the SAW resonator element 41, the MEMS resonator element, or the resonator element, means based on a piezoelectric effect may be used, and electrostatic drive based on a Coulomb's force may be used.

The IDT 412 is constituted by a pair of electrodes 412a and 412b which are provided at the central portion of the quartz crystal substrate 411 in a longitudinal direction. The pair of electrodes 412a and 412b are disposed so that electrode fingers of the electrode 412a and electrode fingers of the electrode 412b are engaged with each other. When a voltage is applied between these pair of electrodes 412a and 412b, periodic distortion occurs between the electrode fingers due to the piezoelectric effect of the quartz crystal substrate 411, and a surface acoustic wave is excited in the quartz crystal substrate 411. The excited surface acoustic wave is propagated along the continuous direction of the electrode fingers.

The pair of reflectors 413 and 414 are disposed on both sides of the IDT 412 in the longitudinal direction of the quartz crystal substrate 411 with the IDT interposed therebetween. The reflectors 413 and 414 have a function of reflecting a surface acoustic wave which is excited in the IDT 412 and propagated to the quartz crystal substrate 411, toward the direction of the IDT 412.

The IDT 412 and the reflectors 413 and 414 described above are formed, as a whole, so as to be shifted to one end side of the quartz crystal substrate 411 in the longitudinal direction, and a pair of bonding pads 415 and 416 are disposed on the upper surface of the quartz crystal substrate 411 on the other end side. In addition, the bonding pad 415 and the electrode 412a are electrically connected to each other through the extraction electrode 417, and the bonding pad 416 and the electrode 412b are electrically connected to each other through the extraction electrode 418.

Such a SAW resonator element 41 is disposed on the ceramic base substrate 46 through a bonding member. In addition, the bonding pads 415 and 416 are electrically connected to the internal terminals 481 and 482 through a bonding wire.

Such a SAW resonator 4 can easily be adapted to a high frequency (frequency in, for example, a band of GHz), for example, as compared to an AT cut quartz crystal resonator. Therefore, the use of the SAW resonator leads to the electronic device 1 appropriate to a high-frequency output. Specifically, since the frequency of the AT cut quartz crystal resonator depends on the thickness of the quartz crystal substrate, the quartz crystal substrate becomes thinner as the frequency becomes higher, and thus processing is likely to be difficult. On the other hand, since the frequency of the SAW resonator depends on the interval between the electrode fingers of the IDT rather than the thickness of the quartz crystal substrate, the interval between the electrode fingers becomes shorter as the frequency becomes higher, but making the interval between the electrode fingers shorter can be easily performed by existing patterning techniques. From such reasons, the use of the SAW resonator leads to the electronic device 1 appropriate to a high frequency.

Such a SAW resonator 4 is connected to the support substrate 3 by a conductive bonding member such as solder, a conductive adhesive, silver solder, or gold solder, and is electrically connected to the oscillation circuit 51 through the conductive bonding member. Meanwhile, the SAW resonator 4 is not particularly limited in the arrangement thereof, but is preferably disposed so as to overlap the end side of the support substrate 3 in the long-axis direction as shown in FIG. 8. The end side herein refers to the lateral side 3c rather than a line segment linking the solders H1 and H4. Since such a portion serves as a free end which is not fixed to the base substrate 21, stress which is generated due to thermal expansion is smaller than in other portion (central portion). Therefore, the SAW resonator 4 is disposed so as to overlap such a portion, whereby stress is not likely to be applied to the SAW resonator 4, and thus further stabilized drive can be performed.

As stated above, the configuration of the electronic device 1 has been described in detail. Particularly, since the cavity 211 is formed in the base substrate 21, and the cavity 271 is formed in the main body 272 of the lid 27, a relatively large internal space S which is formed by the cavities 211 and 271 can be provided inside the package 2. Therefore, the SAW resonator 4 and the circuit 5 are easily provided within the package 2.

In addition, in the electronic device 1, since the support substrate 3 is bonded to the upper surface of the base substrate 21, the support substrate 3 functions as a reinforcement member that reinforces the mechanical strength of the base substrate 21. Therefore, it is possible to increase the mechanical strength of the electronic device 1. In addition, as described above, a region except for both ends of the lateral side 3a of the support substrate 3 and a region except for both ends of the lateral side 3b thereof are bonded to the upper surface along the lateral side 21a of the base substrate 21 and the upper surface along the lateral side 21b thereof through the solders H1 to H6. Therefore, both ends of the support substrate 3 in the long-axis direction are unrestrained with respect to the base substrate 21, and the thermal expansion of the portion can be allowed. Thereby, stress caused by the thermal expansion of the portion is not likely to be generated. It is possible to reduce stress which is generated due to a thermal expansion difference between the base substrate 21 and the support substrate 3 to that extent, and to reduce damage of the base substrate 21 and the support substrate 3, the generation of cracks in the solders H1 to H6, or the like which is caused by the stress. From the above, the electronic device 1 having high reliability is obtained.

In addition, the SAW resonator 4 and the circuit 5 are provided on the support substrate 3, and thus it is possible to effectively use the support substrate 3. Particularly, in the present embodiment, since arrangement spaces are secured on the upper surface side and the lower surface side of the support substrate 3, respectively, it is possible to dispose the SAW resonator 4 and the circuit 5 with a sufficient margin therebetween.

Further, in the electronic device 1, the lid 27 is fixed to the lateral sides 21c and 21d of the base substrate 21. Therefore, the electronic device 1 has a structure in which the bending of the base substrate 21 in a long-axis direction and a short-axis direction is suppressed by the support substrate 3, and the bending of the base substrate 21 in a long-axis direction is suppressed by the lid 27. Thereby, the bending of the base substrate 21 is further reduced, and thus it is possible to further increase the mechanical strength of the base substrate 21.

### Second Embodiment

Next, an electronic device according to a second embodiment of the invention will be described.

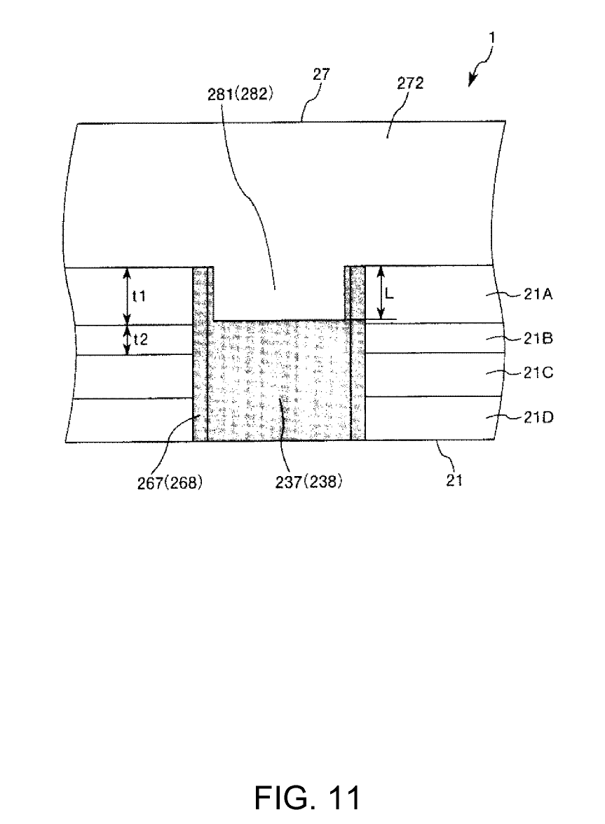

FIG. 11 is a side view illustrating the electronic device according to the second embodiment of the invention.

Hereinafter, the electronic device according to the second embodiment of the invention will be described, but a description will be given with focus on differences from the aforementioned embodiment, and common particulars will not be described below.

The electronic device of the second embodiment is the same as that of the aforementioned first embodiment, except that the thicknesses of the first substrate and the second substrate are different from each other. Meanwhile, the same components as those of the aforementioned embodiment are denoted by the same reference numerals and signs.

As shown in FIG. 11, in the electronic device 1 of the present embodiment, the thickness of the first substrate 21A constituting the base substrate 21 is larger than the thickness of the second substrate 21B. That is, when the thickness of the first substrate 21A is set to t1, and the thickness of the second substrate 21B is set to t2, the relation of t1>t2 is satisfied. Such a relation is satisfied, and thus, for example, the length L of the claw portions 281 and 282 can be made to be larger than that of the base substrate 21 which has a thickness equal to the total thickness of the first and second substrates 21A and 21B, and in which the relation of t1=t2 (or t1<t2) is satisfied. Therefore, it is possible to more reliably connect the claw portions 281 and 282 to the castellations 267 and 268 without increasing the thickness of the base substrate 21, and to more reliably bond the lid 27 to the base substrate 21 through the solder H.

In the second embodiment described above, it is also possible to exhibit the same effect as that of the aforementioned first embodiment.

### Third Embodiment

Next, an electronic device according to a third embodiment of the invention will be described.

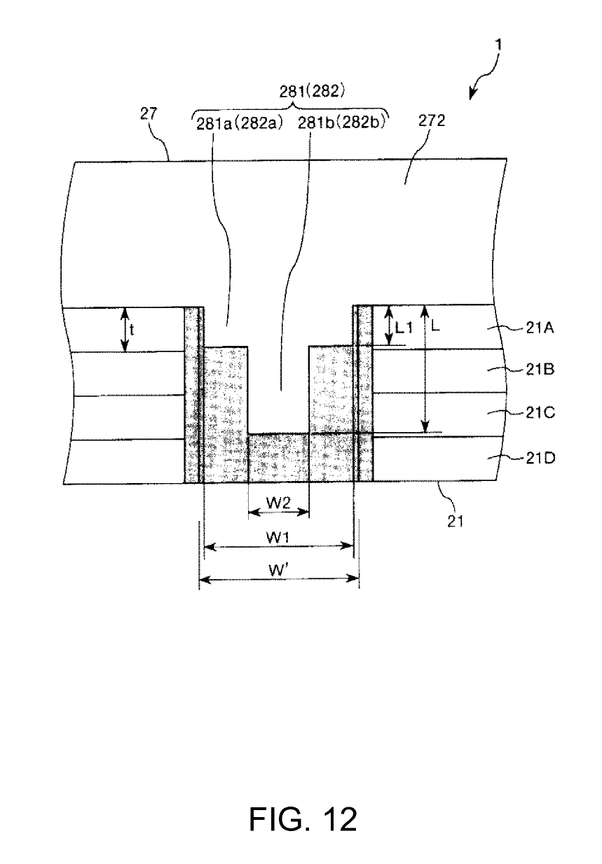

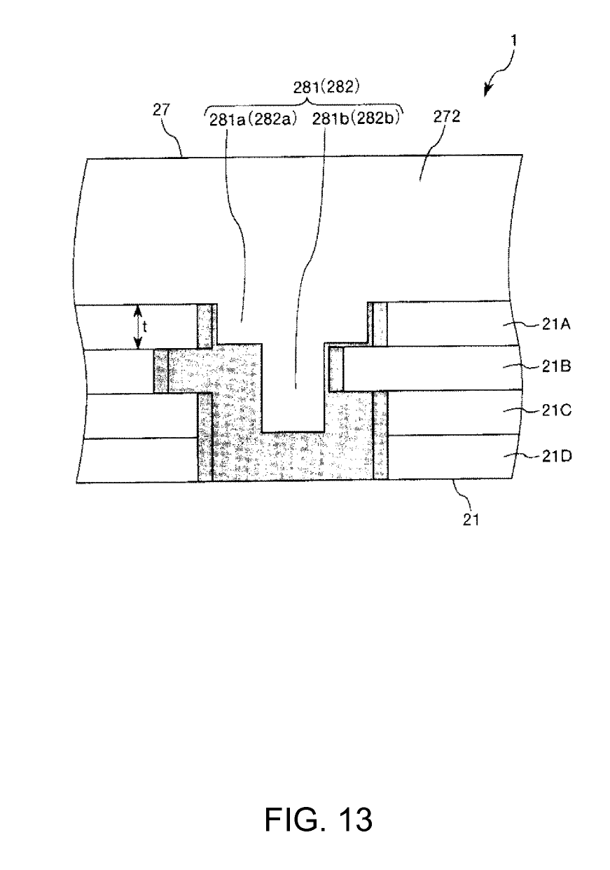

FIGS. 12 and 13 are side views illustrating the electronic device according to the third embodiment of the invention, respectively.

Hereinafter, the electronic device according to the third embodiment of the invention will be described, a description will be given with focus on differences from the aforementioned embodiment, and common particulars will not be described below.

The electronic device of the third embodiment is the same as that of the aforementioned first embodiment, except that the configurations of the claw portions included in the lid are different from the above ones. Meanwhile, the same components as those of the aforementioned embodiment are denoted by the same reference numerals and signs.

In the electronic device 1 of the present embodiment, as shown in FIG. 12, the claw portion 281 includes a first claw portion 281a protruding from the main body 272 and a second claw portion 281b protruding from the apical end of the first claw portion 281a. Similarly, the claw portion 282 includes a first claw portion 282a protruding from the main body 272 and a second claw portion 282b protruding from the apical end of the first claw portion 282a. The total length L of such claw portions 281 and 282 is larger than the thickness t of the first substrate 21A. That is, the relation of L>t is satisfied.

In addition, the length L1 of the first claw portions 281a and 282a is equal to or less than the thickness t of the first substrate 21A. That is, the relation of L1≦t is satisfied. In addition, it is preferable that the width W1 of the first claw portions 281a and 282a is almost equal to the width W′ of the notched portions 237 and 238 (castellations 267 and 268) on the surface where the claw portions 281 and 282 are located. More specifically, it is preferable that the width W1 satisfies, for example, the relation of 0.9W′≦W1≦1.1W′.

In addition, the width W2 of the second claw portions 281b and 282b is smaller than the width W1 of the first claw portions 281a and 282b. That is, the relation of W2<W1 is satisfied. In addition, the second claw portions 281b and 282b protrude from the central portion except both ends of the first claw portions 281a and 281b in a width direction, and the central lines of the first claw portions 281a and 282a and the second claw portions 281b and 282b are substantially coincident with each other. However, the positions of the second claw portions 281b and 282b are not limited thereto, and may be disposed biased to one end side of the first claw portions 281a and 282a in a width direction.

In the electronic device 1 having such a configuration, it is possible to exhibit the following effect. As described above, since the base substrate 21 is formed of a laminated substrate in which the first to fourth substrates 21A to 21D are laminated, for example, as shown in FIG. 13, lamination misalignment may occur during manufacturing, and the second substrate 21B may be misaligned with respect to the other substrates 21A, 21C, and 21D. Even in such a case, the second claw portions 281b and 282b which are located on the apical end side of the claw portions 281 and 282 are made thinner, and thus the claw portions 281 and 282 can be inserted into the notched portions 237 and 238 without catching on a misaligned portion. Additionally, the length L1 of the first claw portions 281a and 282a which are located on the base portion side is set to be equal to or less than the thickness t of the first substrate 21A, and thus striking on the second substrate 21B is prevented. Therefore, it is possible to insert the claw portions 281 and 282 into the notched portions 237 and 238 up to a predetermined depth (until the lower surface of the main body 272 comes into contact with the upper surface of the base substrate 21), and to dispose the lid 27 at a desired position with respect to the base substrate 21.

Meanwhile, even when the entirety of the claw portions 281 and 282 in a length direction is reduced in thickness to the same degree as the second claw portions 281b and 282b, the above effect can be exhibited, but in this case, there is a problem in that the misalignment of the lid 27 in an in-plane direction (short-axis direction and long-axis direction) with respect to the base substrate 21 increases. On the other hand, in the present embodiment, as described above, the width W1 of the first claw portions 281a and 282a is made as large as that of the notched portions 237 and 238, and thus the misalignment of the lid 27 in an in-plane direction (short-axis direction and long-axis direction) with respect to the base substrate 21 is reduced.

That is, according to the electronic device 1 of the present embodiment, the lid 27 can be disposed three-dimensionally at a predetermined position with respect to the base substrate 21.

### 2. Electronic Apparatus

Next, an electronic apparatus including the electronic device 1 will be described.

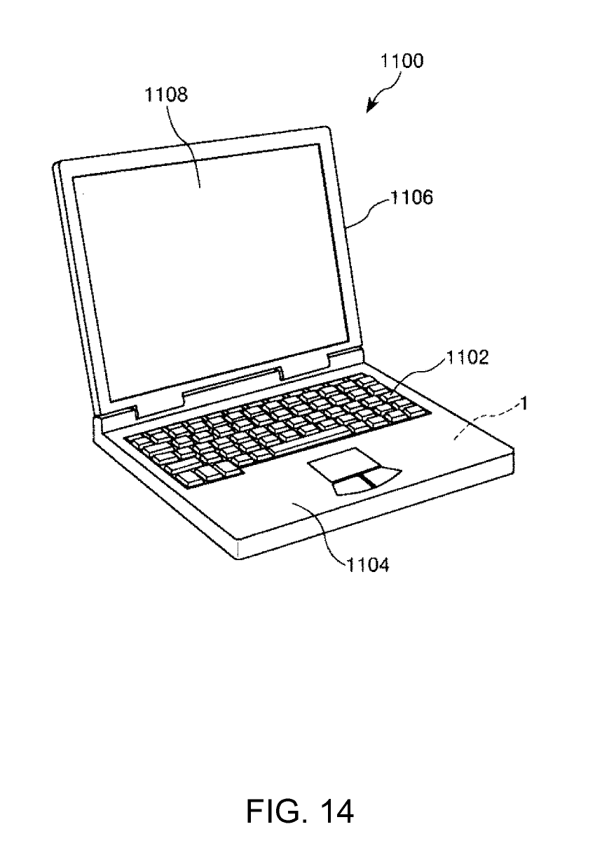

FIG. 14 is a perspective view illustrating a configuration of a mobile-type (or note-type) personal computer to which the electronic apparatus according to the invention is applied. In this drawing, a personal computer 1100 is constituted by a main body 1104 including a keyboard 1102 and a display unit 1106 including a display portion 1108, and the display unit 1106 is rotatably supported with respect to the main body 1104 through a hinge structure. Such a personal computer 1100 has the built-in electronic device 1 functioning as a filter, a resonator, a reference clock, or the like.

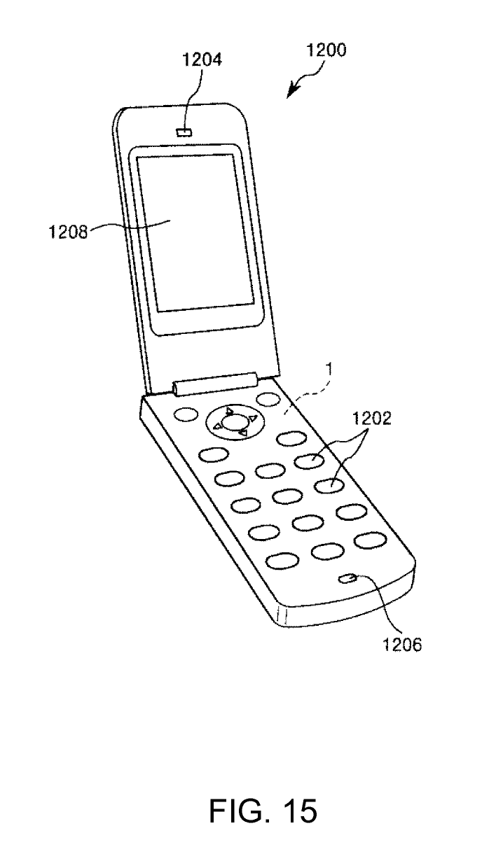

FIG. 15 is a perspective view illustrating a configuration of a cellular phone (also including PHS) to which the electronic apparatus according to the invention is applied. In this drawing, a cellular phone 1200 includes a plurality of operation buttons 1202, an ear piece 1204 and a mouth piece 1206, and a display portion 1208 is disposed between the operation buttons 1202 and the ear piece 1204. Such a cellular phone 1200 has the built-in electronic device 1 functioning as a filter, a resonator, a reference clock, or the like.

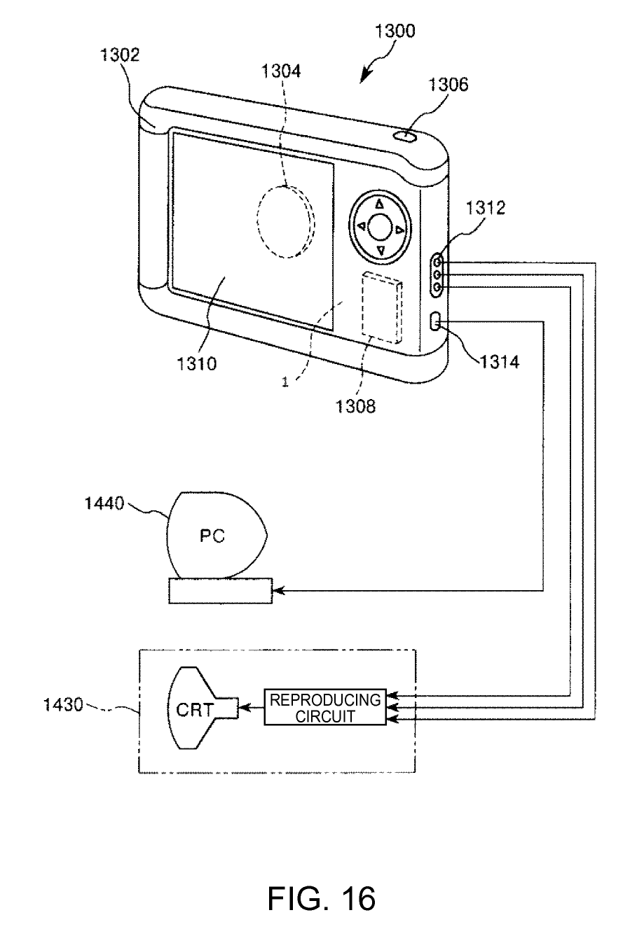

FIG. 16 is a perspective view illustrating a configuration of a digital still camera to which the electronic apparatus according to the invention is applied. Meanwhile, in the drawing, the connection with an external device is also shown simply. Here, a normal camera exposes a silver halide photo film through a light image of a subject, whereas a digital still camera 1300 generates an imaging signal (image signal) by photoelectrically converting a light image of a subject using an imaging device such as a CCD (Charge Coupled Device).

A display portion 1310 is provided on the rear of a case (body) 1302 in the digital still camera 1300, and is configured to perform a display on the basis of an imaging signal of a CCD. The display portion functions as a viewfinder for displaying a subject as an electronic image. In addition, a light-receiving unit 1304 including an optical lens (imaging optical system), a CCD and the like is provided on the front side (back side in the drawing) of the case 1302.

When a photographer confirms a subject image displayed on the display portion and pushes a shutter button 1306, an imaging signal of the CCD at that point in time is transmitted and stored to and in a memory 1308. In addition, in the digital still camera 1300, a video signal output terminal 1312 and an input and output terminal 1314 for data communication are provided on the lateral side of the case 1302. As shown in the drawing, a TV monitor 1430 is connected to the video signal output terminal 1312, and a personal computer 1440 is connected to the input and output terminal 1314 for data communication, respectively as necessary. Further, the imaging signal stored in the memory 1308 is output to the TV monitor 1430 or the personal computer 1440 by a predetermined operation. Such a digital still camera 1300 has the built-in electronic device 1 functioning as a filter, a resonator, a reference clock, or the like.

Meanwhile, in addition to the personal computer (mobile-type personal computer) of FIG. 14, the cellular phone of FIG. 15, and the digital still camera of FIG. 16, the electronic apparatus including the electronic device can be applied to, for example, a mobile terminal such as a smartphone, a communication device, an ink jet ejecting apparatus (for example, ink jet printer), a laptop personal computer, a tablet personal computer, a storage area network device such as a router or a switch, a local area network device, a device for a mobile terminal and a base station, a television, a video camera, a video recorder, a car navigation device, a real-time clock device, a pager, an electronic notebook (including one with a communication function), an electronic dictionary, an electronic calculator, an electronic game console, a word processor, a workstation, a TV phone, a security TV monitor, electronic binoculars, a POS terminal, a medical instrument (for example, an electronic thermometer, a sphygmomanometer, a blood glucose monitoring system, an electrocardiogram measurement device, an ultrasound diagnostic device, or an electronic endoscope), a fish finder, various types of measuring apparatuses, meters and gauges (for example, meters and gauges of a vehicle, an airplane, or a vessel), a flight simulator, a head mounted display, a motion tracer, a motion tracker, a motion controller, a PDR (walker position and direction measurement), and the like.

### 3. Moving Object

Next, a moving object including the electronic device 1 will be described.

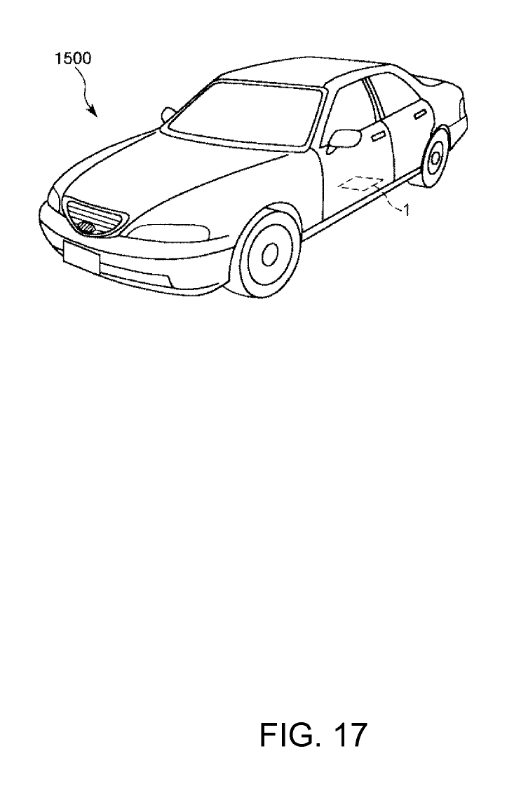

FIG. 17 is a perspective view illustrating an automobile to which the moving object is applied. The electronic device 1 is mounted to an automobile 1500. The electronic device 1 can be applied widely to, for example, electronic control units (ECUs) such as a keyless entry, an immobilizer, a car navigation system, a car air conditioner, an antilock brake system (ABS), an air bag, a tire pressure monitoring system (TPMS), an engine controller, a braking system, a battery monitor of a hybrid automobile or an electric automobile, and a car-body posture control system.

As described above, the electronic device, the electronic apparatus and the moving object according to the invention have been described on the basis of the shown embodiments, but the invention is not limited thereto, and the configuration of each portion can be replaced by any configuration having the same function. In addition, any other configurations may be added to the invention. In addition, the invention may be configured such that any two or more configurations in the above embodiments are combined.

In addition, in the aforementioned embodiment, a configuration has been described in which the SAW resonator element is used as the resonator element, but the resonator element is not limited thereto. For example, as the resonator element, an AT cut quartz crystal resonator (thickness-shear mode resonator) element may be used, and a tuning fork-type resonator (flexural resonator) element may be used. In addition, in the aforementioned embodiment, a configuration has been described in which the electronic device is applied to the voltage controlled SAW oscillator (VCSO), but in addition to this, the electronic device can be applied to an oscillator such as a SAW oscillator (SPSO), a crystal oscillator (SPXO), a voltage-controlled crystal oscillator (VCXO), a temperature-compensated crystal oscillator (TCXO), an oven-controlled crystal oscillator (OCXO), or a MEMS oscillator, an inertial sensor such as an acceleration sensor and a gyro sensor, and a physical quantity sensor such as a force sensor of an inclination sensor.

In addition, in the aforementioned embodiment, a configuration in which the support substrate is disposed within the package has been described, but the support substrate may be omitted. In addition, a component which is disposed within the package may not be limited to a resonator or a circuit.

The entire disclosure of Japanese Patent Application No. 2014-046981, filed Mar. 10, 2014 is expressly incorporated by reference herein.

What is claimed is:

1. A electronic device comprising:
abase substrate including a first substrate and a second substrate which are laminated; and
a lid which is bonded to the first substrate side of the base substrate,
wherein the base substrate is configured such that a notched portion is provided on a lateral side throughout the second substrate from the first substrate in the lamination direction, and that a metal film is present on an inner surface of a region of the first substrate in the notched portion,
the lid includes
a main body that faces the base substrate, and
a first claw portion, protruding from the main body to a region facing the notched portion, which is bonded to the metal film through a bonding member, and
a length of the first claw portion along the lamination direction is equal to or less than a thickness of the first substrate along the lamination direction.

2. The electronic device according to claim 1, further comprising a second claw portion, extending from the first claw portion, of which a length in a direction intersecting a direction in which the first claw portion protrudes from the main body is shorter than that of the first claw portion.

3. The electronic device according to claim 1, wherein the lid and the bonding member have a conductive property,
the lid is electrically connected to the metal film through the bonding member, and
the metal film is connected to a reference potential.

4. The electronic device according to claim 2, wherein the lid and the bonding member have a conductive property,
the lid is electrically connected to the metal film through the bonding member, and
the metal film is connected to a reference potential.

5. The electronic device according to claim 1, wherein the first substrate is larger in thickness than the second substrate.

6. The electronic device according to claim 2, wherein the first substrate is larger in thickness than the second substrate.

7. The electronic device according to claim 3, wherein the first substrate is larger in thickness than the second substrate.

8. The electronic device according to claim 1, wherein the base substrate has a cavity which is open to a main surface of the lid side, and
the main body of the lid has a cavity which is open to a main surface of the base substrate side.

9. The electronic device according to claim 3, wherein the base substrate has a cavity which is open to a main surface of the lid side, and
the main body of the lid has a cavity which is open to a main surface of the base substrate side.

10. The electronic device according to claim 5, wherein the base substrate has a cavity which is open to a main surface of the lid side, and
the main body of the lid has a cavity which is open to a main surface of the base substrate side.

11. The electronic device according to claim 8, further comprising an internal substrate, connected to the base substrate, within a space which is formed by a cavity of the base substrate and a cavity of the lid.

12. The electronic device according to claim 9, further comprising an internal substrate, connected to the base substrate, within a space which is formed by a cavity of the base substrate and a cavity of the lid.

13. The electronic device according to claim 10, further comprising an internal substrate, connected to the base substrate, within a space which is formed by a cavity of the base substrate and a cavity of the lid.

14. The electronic device according to claim 11, wherein the internal substrate is provided with a resonator and a circuit which is connected to the resonator.

15. The electronic device according to claim 12, wherein the internal substrate is provided with a resonator and a circuit which is connected to the resonator.

16. The electronic device according to claim 13, wherein the internal substrate is provided with a resonator and a circuit which is connected to the resonator.

17. An electronic apparatus comprising the electronic device according to claim 1.

18. A moving object comprising the electronic device according to claim 1.
